(19) United States
(12) Patent Application Publication
(10) Pub. No.: US 2009/0205570 A1
(43) Pub. Date: Aug. 20, 2009

(54) Gas supply unit and chemical vapor deposition apparatus

(75) Inventor: Hyung-Dong Kang, Yongin-si (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 12/216,249

(22) Filed: Jul. 1, 2008

(30) Foreign Application Priority Data
Feb. 14, 2008 (KR) 10-2008-0013385

(51) Int. Cl. C23C 16/00

(52) U.S. Cl. 118/715

(57) ABSTRACT

A gas supply unit and a chemical vapor deposition apparatus are disclosed. A gas supply unit for supplying a reactive gas for a chemical vapor deposition process can include a hot wire part configured to pyrolyze the reactive gas, an ejection part configured to eject the reactive gas towards the hot wire part, and a suction part disposed adjacent to the hot wire part and configured to suck in and exhaust a by-product of the reactive gas. With certain embodiments of the invention, the by-products resulting from the chemical vapor deposition process may be exhausted immediately, so that a thin film may be formed over an object with higher quality, and the cleaning cycles for the inside of the chamber may be extended, for greater productivity.

### CROSS-REFERENCE TO RELATED APPLICATIONS

This application claims the benefit of Korean Patent Application No. 10-2008-0013385 filed with the Korean Intellectual Property Office on Feb. 14, 2008, the disclosure of which is incorporated herein by reference in its entirety.

### BACKGROUND

1. Technical Field

The present invention relates to a gas supply unit and to a chemical vapor deposition apparatus.

2. Description of the Related Art

Methods of depositing a thin film over an object include physical vapor deposition (PVD) and chemical vapor deposition (CVD), etc. Chemical vapor deposition is a method of ejecting a reactive gas into a chamber, decomposing the gas by applying suitable levels of activity and thermal energy, and creating a particular chemical reaction on the object, to deposit a thin film over the surface of the object.

FIG. 1 is a schematic drawing of a chemical vapor deposition apparatus according to the related art. The chemical vapor deposition apparatus may include such elements as a chamber 1 that is isolated from the exterior and placed in a decompressed state, a shower head 7 for ejecting a reactive gas into the chamber 1, a hot wire 8 for decomposing the reactive gas ejected through the shower head 7 by applying heat, a chuck 5 on which the object 4 may be mounted, and an exhaust pipe 2 formed in one side of the chamber 1 through which the reactive gas diffused in the chamber 1 may be exhausted.

In the chemical vapor deposition apparatus according to the related art, the reactive gas may be ejected through the shower head, and as the reactive gas is pyrolyzed by the hot wire, components of the pyrolyzed reactive gas may undergo a chemical reaction at the surface of the object to form a thin film.

In this case, not all of the reactive gas inserted through the shower head into the chamber may undergo pyrolysis, and not all of the relevant components from the pyrolyzed reactive gas may be deposited over the surface of the object. The reactive gas that has not pyrolyzed and the components of the gas that has pyrolyzed may be diffused inside of the chamber. These by-products of the reaction may contaminate the thin film formed over the surface of the object, resulting in defects in the final product, and/or may be adsorbed on the inner walls of the chamber, making it necessary to clean the chamber frequently.

An exhaust pipe can be used to exhaust the by-products diffused inside the chamber, but the exhaust pipe may not sufficiently exhaust the by-products, and the problems of defective products and adsorption on the inner walls of the chamber may remain.

### SUMMARY

An aspect of the invention provides a gas supply unit and a chemical vapor deposition apparatus that can immediately exhaust the by-products of the chemical vapor deposition process, to form a thin film may over an object with higher quality, extend the cleaning cycles for the inside of the chamber, and thereby improve productivity.

Another aspect of the invention provides a gas supply unit for supplying a reactive gas for a chemical vapor deposition process. The gas supply unit can include a hot wire part configured to pyrolyze the reactive gas, an ejection part configured to eject the reactive gas towards the hot wire part, and a suction part disposed adjacent to the hot wire part and configured to suck in and exhaust a by-product of the reactive gas.

The ejection part can include an ejector, which may include a plurality of nozzles, so as to eject the reactive gas evenly.

Yet another aspect of the invention provides an apparatus for depositing a thin film over an object by a chemical vapor deposition process. The apparatus can include a chamber, a support part held inside the chamber and supporting the object, and a gas supply unit that can be attached to and detached from an inside of the chamber. The gas supply unit can be positioned facing the object and can supply a reactive gas to the object. Here, the gas supply unit may include a hot wire part configured to pyrolyze the reactive gas, an ejection part configured to eject the reactive gas towards the hot wire part, and a suction part disposed adjacent to the hot wire part and configured to suck in and exhaust a by-product of the reactive gas.

The ejection part can include an ejector, which may include a plurality of nozzles, so as to eject the reactive gas evenly.

The support part and the gas supply unit can be configured to move in relation to each other.

The support part can include a heater that heats the object.

A multiple number of gas supply units can be arranged. In this case, the gas supply units may eject different reactive gases. Also, the gas supply units can be arranged in a line, with the support part configured to move along the line of gas supply units.

Annealing units may be included, each disposed adjacent to one of the gas supply units.

Additional aspects and advantages of the present invention will be set forth in part in the description which follows, and in part will be obvious from the description, or may be learned by practice of the invention.

### BRIEF DESCRIPTION OF THE DRAWINGS

FIG. 1 is a schematic drawing of a chemical vapor deposition apparatus according to the related art.

FIG. 2 is an elevational view of a gas supply unit according to an embodiment of the invention, as seen from one side.

FIG. 3 is an elevational view of a gas supply unit according to an embodiment of the invention, as seen from another side.

FIG. 4 is a schematic drawing of a chemical vapor deposition apparatus according to another embodiment of the invention.

FIG. 5, FIG. 6, FIG. 7, FIG. 8, FIG. 9, and FIG. 10 are schematic drawings representing a flow diagram for a method of depositing a thin film using a chemical vapor deposition apparatus according to another embodiment of the invention.

FIG. 11 is a schematic drawing of a chemical vapor deposition apparatus according to yet another embodiment of the invention.

FIG. 12 is a schematic drawing illustrating a method of depositing a thin film using a chemical vapor deposition apparatus according to yet another embodiment of the invention.

### DETAILED DESCRIPTION

As the invention allows for various changes and numerous embodiments, particular embodiments will be illustrated in the drawings and described in detail in the written description. However, this is not intended to limit the present invention to particular modes of practice, and it is to be appreciated that all changes, equivalents, and substitutes that do not depart from the spirit and technical scope of the present invention are encompassed in the present invention. In the description of the present invention, certain detailed explanations of related art are omitted when it is deemed that they may unnecessarily obscure the essence of the invention.

The terms used in the present specification are merely used to describe particular embodiments, and are not intended to limit the present invention. An expression used in the singular encompasses the expression of the plural, unless it has a clearly different meaning in the context. In the present specification, it is to be understood that the terms such as “including” or “having,” etc., are intended to indicate the existence of the features, numbers, steps, actions, elements, parts, or combinations thereof disclosed in the specification, and are not intended to preclude the possibility that one or more other features, numbers, steps, actions, elements, parts, or combinations thereof may exist or may be added.

The gas supply unit and chemical vapor deposition apparatus according to certain embodiments of the invention will be described below in more detail with reference to the accompanying drawings. Those elements that are the same or are in correspondence are rendered the same reference numeral regardless of the figure number, and redundant explanations are omitted.

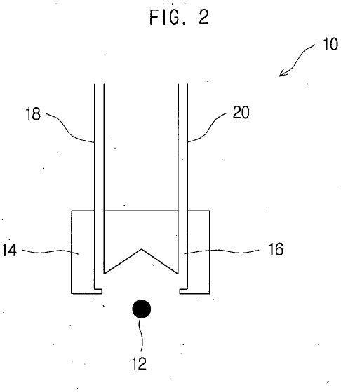

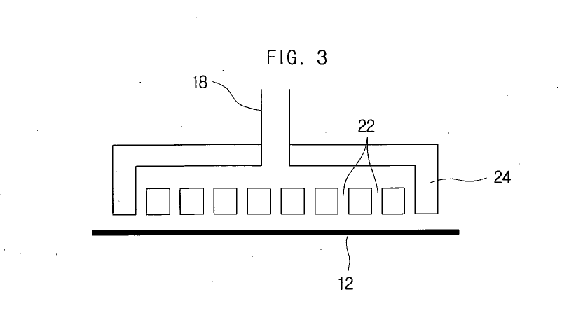

FIG. 2 is an elevational view of a gas supply unit according to an embodiment of the invention seen from one side, and FIG. 3 is an elevational view of a gas supply unit according to an embodiment of the invention seen from another side. In FIGS. 2 and 3, there are illustrated a gas supply unit 10, a hot wire part 12, an ejection part 14, a suction part 16, a gas inlet 18, a gas outlet 20, nozzles 22, and an ejector 24.

The gas supply unit 10 of this embodiment can be a unit for supplying a reactive gas into a chamber during a chemical vapor deposition process. The gas supply unit 10 can include a hot wire part 12 that pyrolyzes the reactive gas, an ejection part 14 that ejects the reactive gas towards the hot wire part 12, and a suction part 16 positioned adjacent to the hot wire part 12 that sucks in and exhausts by-products of the reactive gas. Thus, the by-products resulting from the chemical vapor deposition process may be exhausted immediately, so that a thin film may be formed over an object with higher quality, and the cleaning cycles for the inside of the chamber may be extended, for greater productivity.

In the gas supply unit 10 of this embodiment, when a reactive gas is ejected through the ejection part 14, the ejected reactive gas can be pyrolyzed by the hot wire part 12. The components of the pyrolyzed reactive gas may undergo a chemical reaction at the surface of the object of deposition and may thereby form a thin film. Here, the by-products obtained after the reaction of the reactive gas can be immediately sucked in through the suction part 16, to prevent the by-products from diffusing excessively within the chamber, and thereby prevent defects caused by the by-products. Furthermore, the by-products can be prevented from being adsorbed onto the chamber inner walls, so that the cleaning cycles for the inside of the chamber can be extended, and productivity can be improved. The rate of usage of the reactive gas can be maximized, and the amount of unnecessarily expended reactive gas can be reduced.

Not all of the reactive gas provided through the ejection part 14 into the chamber may be pyrolyzed by the hot wire part 12, and neither may all of the pyrolyzed gas be deposited over the surface of the object. The reactive gas that does not undergo pyrolysis and components of the pyrolyzed gas that are not deposited on the surface of the object, if left to be diffused as by-products inside the chamber, may cause problems such as those described above.

In the gas supply unit 10 according to this embodiment, the reaction by-products resulting from the reactive gas can be immediately drawn in, through the suction part 16 placed adjacent to the hot wire part 12, and exhausted to the outside of the chamber, to prevent possible problems induced by the reaction by-products such as those described above.

The hot wire part 12 can apply high levels of heat to the reactive gas ejected through the ejection part 14, to decompose the gas to ion or radical phase materials. The hot wire part 12 can include a filament, and a power supply device that supplies power to the filament. As the power supply provides electrical power to the filament, the filament may generate heat, which can be used for the pyrolysis of the reactive gas.

Various types of gases can be used for the reactive gas, according to the desired type of thin film to be deposited over the object. For example, if a silicon (Si) thin film is to be deposited over the object, gases such as SiH₄, Si₂H, SiH₂Cl₂, etc., can be used for the reactive gas.

The ejection part 14 can eject the reactive gas onto the hot wire part 12, at which the reactive gas ejected through the ejection part 14 may be pyrolyzed by the high level of heat supplied by the hot wire part 12. The ejection part 14 can be positioned facing the object of deposition, so that the reactive gas ejected through the ejection part 14 may pass the hot wire part 12 for pyrolysis and undergo a chemical reaction at the surface of the object to form a thin film.

In order that the reactive gas may be ejected evenly over the surface, the ejection part 14 can include an ejector 24 in which multiple nozzles 22 are formed. The ejection part 14 can also include a gas storage part, and a gas inlet 18 that connects the ejector 24 with the gas storage part.

The suction part 16 can suck in the by-products of the reactive gas and exhaust the by-products outside the chamber. The suction part 16 can be arranged adjacent to the hot wire part 12, to immediately draw in and exhaust the by-products after the reaction of the reactive gas. The suction part 16 can include a vacuum pump, and a gas outlet 20 through which the vacuum pump may exhaust the reaction by-products to the exterior.

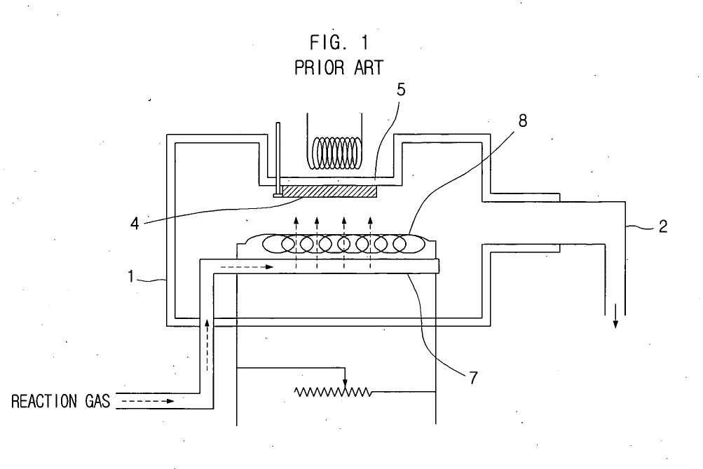

According to the related art, the reaction by-products diffused inside the chamber may be exhausted to the outside through an exhaust pipe coupled in one side of the chamber, as in the example illustrated in FIG. 1, but there may still be a considerable amount of by-products remaining inside the chamber. According to this embodiment of the invention, therefore, the by-products of the reactive gas after the reaction can be exhausted to the exterior immediately through the suction part 16, to prevent the by-products from excessively diffusing throughout the inside of the chamber. This can lower the defect rate in the products and can extend the cleaning cycles for the chamber inner walls, and thus improve productivity.

In certain implementations, the ejection part 14 can be arranged adjacent to the hot wire part 12, so that the hot wire part 12, ejection part 14, and suction part 16 can be modularized into an integrated form.

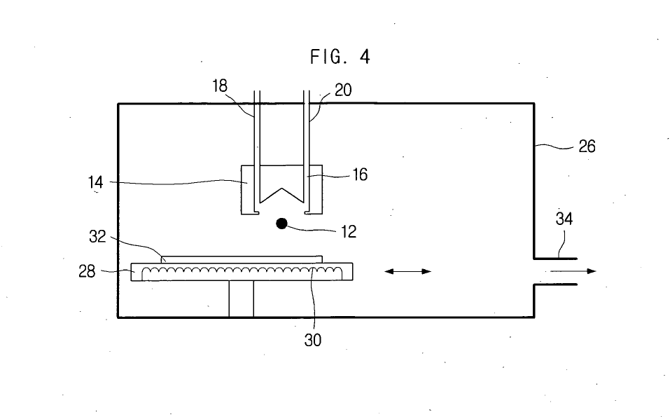

FIG. 4 is a schematic drawing of a chemical vapor deposition apparatus according to another embodiment of the invention. In FIG. 4, there are illustrated a hot wire part 12, an ejection part 14, a suction part 16, a gas inlet 18, a gas outlet 20, a chamber 26, a support part 28, a heater 30, an object 32 of deposition, and an exhaust part 34.

The chemical vapor deposition apparatus of this embodiment can be an apparatus for supplying a reactive gas to deposit a thin film over an object 32 in a chemical vapor deposition process. The apparatus can include a chamber 26, a support part 28, which can be held inside the chamber 26 and which can support the object 32, and a gas supply unit 10, which can be attached to and detached from an inside of the chamber 26, and which can face the object 32 and supply a reactive gas to the object 32. The gas supply unit 10 may in turn include a hot wire part 12 that pyrolyzes the reactive gas, an ejection part 14 that ejects the reactive gas towards the hot wire part 12, and a suction part 16 positioned adjacent to the hot wire part 12 that sucks in and exhausts by-products of the reactive gas. The chemical vapor deposition apparatus of this embodiment can immediately exhaust the by-products produced by the chemical vapor deposition process, to form a higher-quality thin film over an object 32 and extend the cleaning cycles for the inner walls of the chamber 26, and thereby improve productivity.

In the chemical vapor deposition apparatus based on this embodiment, the gas supply unit 10 of the previously described embodiment can be included in a modularized form, to be attached to and detached from an inside of the chamber 26. In this way, thin films can be deposited in larger areas or in multiple layers, according to the needs of the user.

The chamber 26 may include a reaction area isolated from the outside. The thin film can be deposited over the surface of the object 32 by a chemical vapor deposition inside the chamber 26.

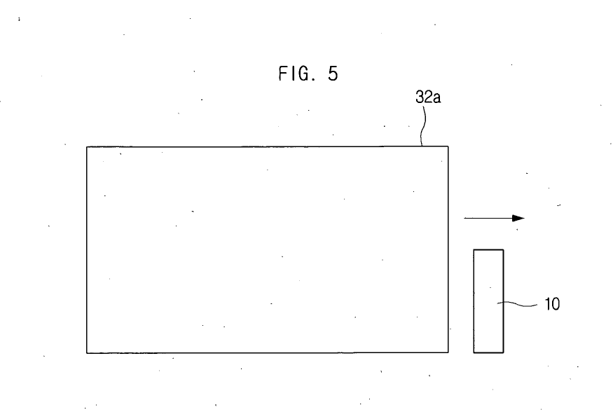

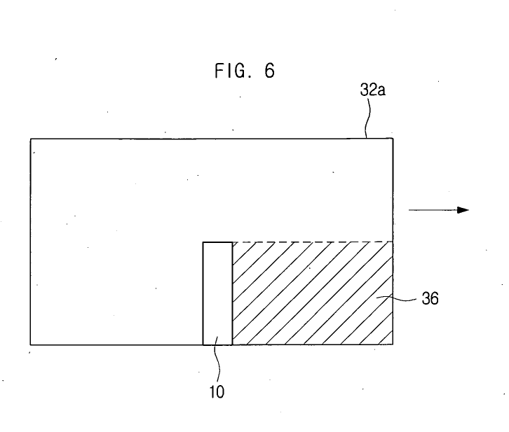

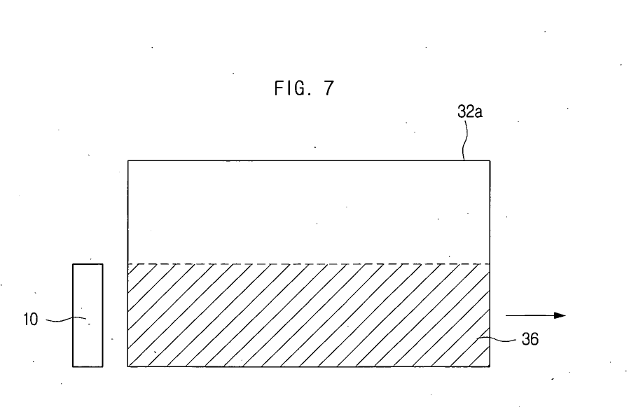

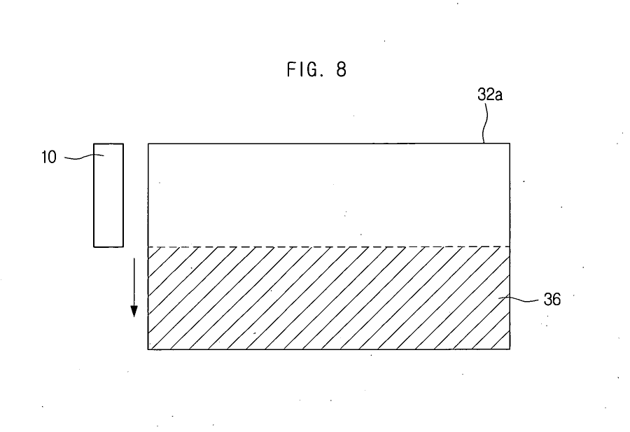

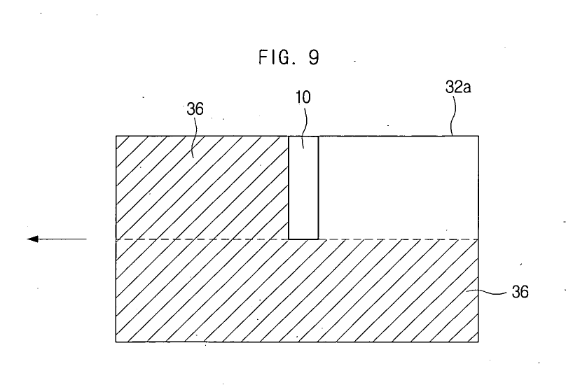

The support part 28 can support the object 32. While this embodiment is described for an example in which the support part 28 is located at a lower portion of the chamber 26, and the gas supply unit 10 is installed above the support part 28, as illustrated in FIG. 5, it is also possible to have the gas supply unit 10 eject a reactive gas from a lower portion of the chamber 26 to an upper portion, with the support part 28 supporting the object 32 above the gas supply unit 10.

The support part 28 can include a heater 30 that applies heat to the object 32 of deposition. As the crystalline formation of the thin film deposited over the object 32 may depend on the temperature of the object 32 during the chemical reaction, the heater 30 can be used to regulate the temperature of the object 32 according to the type of thin film that is to be deposited. For example, it is known that when depositing a silicon thin film over a glass substrate, a silicon thin film of a crystalline structure will be obtained if the temperature of the substrate is over 600 degrees Celsius, whereas a non-crystalline structure will be obtained if the temperature of the substrate is under 600 degrees Celsius.

The gas supply unit 10 can be positioned opposite the object 32 of deposition and can supply the reactive gas to the object 32. Here, the gas supply unit 10 can be modularized, so that the gas supply unit 10 may be attached to or detached from the inside of the chamber 26.

The gas supply unit 16 can include a hot wire part 12 that pyrolyzes the reactive gas, an ejection part 14 that ejects the reactive gas towards the hot wire part 12, and a suction part 16 positioned adjacent to the hot wire part 12 that sucks in the by-products of the reactive gas and exhausts the by-products to the outside of the chamber 26. Elements of the gas supply unit 10 may be substantially the same as those of the previously described embodiment, and thus will not be described again.

The support part 28 and the gas supply unit 10 can be movable in relation to each other. To be “movable in relation to each other” not only means that the gas supply unit 10 may move in relation to the support part 28 and that the support part 28 may move in relation to the gas supply unit 10, but also encompasses those cases in which the support part 28 and the gas supply unit 10 may move independently.

Allowing the support part 28 and the gas supply unit 10 to move in relation to each other can be particularly useful when depositing a thin film over an object 32 having a large area or when depositing an even layer of thin film. This will be described later in further detail with respect to FIGS. 5 to 10.

An exhaust part 34 can be included in one side of the chamber 26, so that the inside of the chamber 26 can be placed in a decompressed state as necessary. Thus, if there is a need to provide a compressed or decompressed environment inside the chamber 26, according to the desired deposition condition, the exhaust part 34 can be used to adjust the internal pressure inside the chamber 26.

FIG. 5 through FIG. 10 are schematic drawings representing a flow diagram for a method of depositing a thin film using a chemical vapor deposition apparatus according to another embodiment of the invention. In FIGS. 5 to 10, there are illustrated a gas supply unit 10, a substrate 32a, and a thin film 36.

This embodiment will be described using an example in which a flat substrate 32a having a large area is used as the object over which a thin film 36 is deposited, where the thin film 36 is deposited over one side of the substrate 32a. The chemical vapor deposition apparatus of this embodiment can be structured to have the gas supply unit 10 secured within the chamber (not shown) and to have the support part (not shown) supporting the object of deposition capable of movement in relation to the gas supply unit 10.

For more convenient explanation, FIG. 5 through FIG. 10 illustrates only the substrate 32a mounted on the support part and the gas supply unit 10.

A method of depositing a thin film 36 over the surface of a large-area substrate 32a can include transporting the lower part of the substrate 32a, using the support part, in the direction of the gas supply unit 10, to first deposit the thin film 36 over the lower part (when seen from above) of the large-area substrate 32a, as illustrated in FIGS. 5 and 6. A thin film 36 may be deposited by the gas supply unit 10 over the surface of the substrate 32a passing below the gas supply unit 10, and as the lower part of the substrate 32a passes below the gas supply unit 10, a thin film 36 may be formed over the lower part of the substrate 32a, as illustrated in FIG. 7. Then, as illustrated in FIG. 8, the substrate 32a can be transported downward (when seen from above) with respect to the gas supply unit 10 to prepare for the process of forming a thin film 36 over the remaining upper part of the substrate 32a. Next, as illustrated in FIGS. 9 and 10, the upper part (when seen from above) of the substrate 32a can be transported in the direction of the gas supply unit 10. As the upper part of the substrate 32a passes below the gas supply unit 10, a thin film 36 may be formed over the upper part of the substrate 32a. These procedures can be repeated to form a thin film 36 evenly over a substrate 32a having a large area.

While this embodiment is described using an example in which the thin film 36 is deposited by securing the gas supply unit 10 and moving the support part, it is also possible to deposit the thin film 36 over the large-area substrate 32a by securing the support part and moving the gas supply unit 10 relative to the support part. Also, for higher efficiency in depositing the thin film 36, it is also possible to deposit the thin film 36 by moving both the support part and the gas supply unit 10.

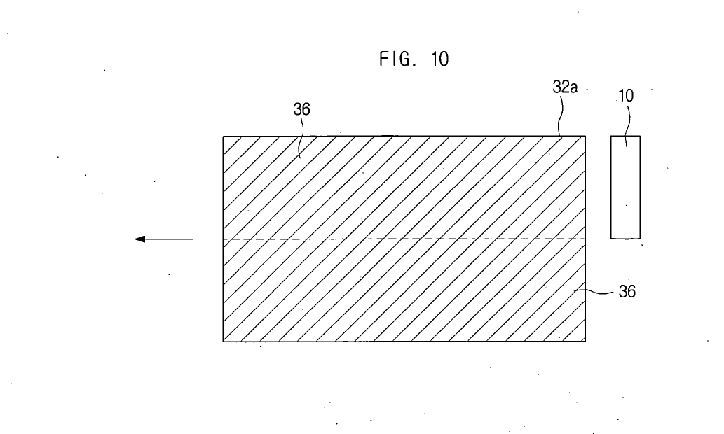

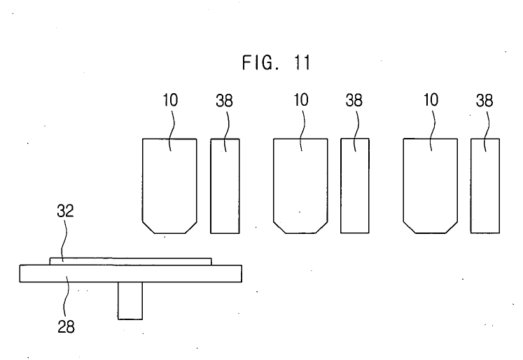

FIG. 11 is a schematic drawing of a chemical vapor deposition apparatus according to yet another embodiment of the invention. In FIG. 11, there are illustrated gas supply units 10, annealing units 38, a support part 28, and an object 32.

The chemical vapor deposition apparatus of this embodiment can include a multiple number of gas supply units 10 inside the chamber (not shown), to deposit a thin film over the surface of an object 32 more quickly, or deposit multiple layers of different thin films simultaneously.

The multiple gas supply units 10 positioned in the chamber can be arranged in a line, with multiple annealing units 38 positioned adjacent to the multiple gas supply units 10 respectively.

In the chemical vapor deposition apparatus according to this embodiment, the gas supply units 10 can be arranged inside the chamber in a line, where each of the multiple gas supply units 10 can form a pair with a respective annealing unit 38.

An annealing unit 38 can be an apparatus for applying post-treatment over the thin film deposited on the object 32 by the gas supply unit 10. The annealing unit 38 may irradiate a laser or an ion beam, apply a plasma surface-treatment, or apply a heat treatment to the thin film.

The support part 28 can transport the object 32 along the line of gas supply units 10, to deposit a thin film of a particular thickness more quickly, or deposit multiple layers of different thin films simultaneously. The multiple gas supply units 10 can be made to eject the same reactive gas or eject different reactive gases.

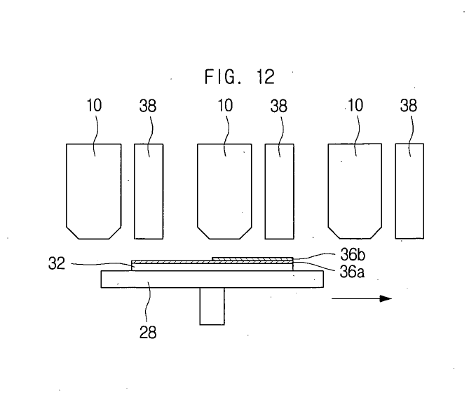

FIG. 12 is a schematic drawing illustrating a method of depositing a thin film using a chemical vapor deposition apparatus according to yet another embodiment of the invention. In FIG. 12, there are illustrated gas supply units 10, annealing units 38, a support part 28, an object 32, a first thin film 36a, and a second thin film 36b.

A multiple number of gas supply units 10 and annealing units can be arranged in a line, and the object 32 of deposition can be mounted on the support part 28 facing the line of gas supply units 10 and annealing units. The support part 28 can transport the object 32 along the gas supply units 10 arranged in a line, to deposit a thin film over the surface of an object 32 more quickly, or deposit multiple layers of different thin films simultaneously.

Referring to FIG. 12, the multiple gas supply units 10 can be arranged in a line, and the support part 28 can transport the object 32 from one side (e.g. the left side in FIG. 12) of the line to the other side (e.g. the right side in FIG. 12). A first thin film 36a can be deposited over the object 32 by the gas supply unit 10 passed first, while the adjacent annealing unit 38 can immediately apply a post-treatment to the first thin film 36a. As the support part 28 moves continuously, a second thin film 36b can be deposited by the next gas supply unit 10, and the annealing unit 38 forming a pair with this gas supply unit 10 can apply a post-treatment to the second thin film 36b. In this way, the support part 28 can transport the object 32 along the gas supply units 10 arranged in a line, to form multiple layers of thin films.

The chemical vapor deposition apparatus according to this embodiment can include three gas supply units 10 and three annealing unit 38 counterparts, so that three layers of thin films can be deposited when the object 32 passes the three pairs of gas supply unit 10 and annealing unit 38 once. If the gas supply units 10 supply the same reactive gas, a thin film of a particular may be deposited more quickly, whereas if the gas supply units 10 supply different reactive gases, multiple layers of different thin films may be deposited. Of course, the type of reactive gas supplied by each gas supply unit 10 may vary according to design conditions.

According to certain embodiments of the invention as set forth above, the by-products resulting from the chemical vapor deposition process may be exhausted immediately, so that a thin film may be formed over an object with higher quality, and the cleaning cycles for the inside of the chamber may be extended, for greater productivity.

Also, the gas supply unit and the object of deposition can be moved relative to each other, so that the rate of deposition can be adjusted, and an even thin film can be obtained.

Furthermore, a multiple number of gas supply units can be arranged in a line, to deposit a thin film of a particular thickness more quickly, or deposit multiple layers of different thin films simultaneously.

While the spirit of the invention has been described in detail with reference to particular embodiments, the embodiments are for illustrative purposes only and do not limit the invention. It is to be appreciated that those skilled in the art can change or modify the embodiments without departing from the scope and spirit of the invention.

What is claimed is:

1. A gas supply unit for supplying a reactive gas for a chemical vapor deposition process, the gas supply unit comprising:
a hot wire part configured to pyrolyze the reactive gas;
an ejection part configured to eject the reactive gas towards the hot wire part; and
a suction part disposed adjacent to the hot wire part and configured to suck in and exhaust a by-product of the reactive gas.

2. The gas supply unit of claim 1, wherein the ejection part comprises an ejector, the ejector having a plurality of nozzles formed therein and configured to eject the reactive gas evenly.

3. An apparatus for depositing a thin film over an object by a chemical vapor deposition process, the apparatus comprising:
a chamber;
a support part held inside the chamber and supporting the object; and
a gas supply unit attachable to and detachable from an inside of the chamber and positioned facing the object, the gas supply unit configured to supply a reactive gas to the object, and the gas supply unit comprising:
a hot wire part configured to pyrolyze the reactive gas;
an ejection part configured to eject the reactive gas towards the hot wire part; and
a suction part disposed adjacent to the hot wire part and configured to suck in and exhaust a by-product of the reactive gas.

4. The apparatus of claim 3, wherein the ejection part comprises an ejector, the ejector having a plurality of nozzles formed therein and configured to eject the reactive gas evenly.

5. The apparatus of claim 3, wherein the support part and the gas supply unit are movable in relation to each other.

6. The apparatus of claim 3, wherein the support part comprises a heater, the heater configured to heat the object.

7. The apparatus of claim 3, including a plurality of gas supply units.

8. The apparatus of claim 7, wherein the plurality of gas supply units eject different reactive gases.

9. The apparatus of claim 7, wherein the plurality of gas supply units are arranged in a line, the support part configured to move along the line of gas supply units.

10. The apparatus of claim 7, comprising an annealing unit each disposed adjacent to each of the plurality of gas supply units.
